(19) United States
(12) Patent Application Publication
(10) Pub. No.: US 2014/0225059 A1
(43) Pub. Date: Aug. 14, 2014

(54) LED with Improved Injection Efficiency

(71) Applicant: BRIDGELUX, INC., Livermore, CA (US)

(72) Inventors: Long Yang, Union City, CA (US); Steve Lester, Palo Alto, CA (US); Jeff Ramer, Sunnyvale, CA (US)

(73) Assignee: BRIDGELUX, INC., Livermore, CA (US)

(21) Appl. No.: 13/763,437

(22) Filed: Feb. 8, 2013

(51) Int. Cl. H01L 33/14; H01L 33/00

(52) U.S. Cl. CPC H01L 33/145; H01L 33/0075
USPC 257/13; 438/47

(57) ABSTRACT

A light-emitting device having an n-type semiconductor layer having a plurality of pits with planar regions between the pits, the pits being characterized by sidewalk that intersect the planar regions is disclosed. A plurality of alternating sub-layers of materials having different bandgaps is deposited on the n-type semiconductor layer. The sub-layers have thicknesses such that the sub-layers form an active layer in the planar regions between the pits and a super lattice on the sidewalls of the pits. A p-type semiconductor layer is deposited on the plurality of alternating sub-layers. One of the sub-layers includes an electron blocking layer. The electron blocking layer is characterized by a first thickness in the substantially planar regions and a second thickness in areas adjacent to the sidewalls of the pits, the second thickness being less than the first thickness.

### BACKGROUND OF THE INVENTION

Light-emitting diodes (LEDs) are an important class of solid-state devices that convert electric energy to light. Improvements in these devices have resulted in their use in light fixtures designed to replace conventional incandescent and fluorescent light sources. The LEDs have significantly longer lifetimes and, in some cases, significantly higher efficiency for converting electric energy to light.

The cost and conversion efficiency of LEDs are important factors in determining the rate at which this new technology will replace conventional light sources and be utilized in high power applications. Many high power applications require multiple LEDs to achieve the needed power levels, since individual LEDs are limited to a few watts. In addition, LEDs generate light in relatively narrow spectral bands. Hence, in applications requiring a light source of a particular color, the light from a number of LEDs with spectral emission in different optical bands is combined or a portion of the light from the LED is converted to light of a different color using a phosphor. Thus, the cost of many light sources based on LEDs is many times the cost of the individual LEDs. To reduce the cost of such light sources, the amount of light generated per LED must be increased without substantially increasing the cost of each LED and without substantially lowering the conversion efficiency of the individual LEDs.

The conversion efficiency of individual LEDs is an important factor in addressing the cost of high power LED light sources. The conversion efficiency of an LED is defined to be the electrical power dissipated per unit of light energy in the desired wavelength range that is emitted by the LED. The energy in light emitted by the LED is the rate of photon production in the desired wavelength range multiplied by the energy of each photon. The electrical power dissipated in the LED is the electrical current through the device multiplied by the voltage across the device. This electrical power efficiency is sometimes referred to as the “wall-plug” efficiency.

Electrical power that is not converted to light in the LED is converted to heat that raises the temperature of the LED. Heat dissipation places a limit on the power level at which an LED operates. In addition, the LEDs must be mounted on structures that provide heat dissipation, which, in turn, further increases the cost of the light sources. Hence, if the wall-plug efficiency of an LED can be increased, the maximum amount of light that can be provided by a single LED can also be increased, and hence, the number of LEDs needed for a given light source can be reduced. In addition, the cost of operation of the LED is also inversely proportional to the wall-plug efficiency. Hence, there has been a great deal of work directed to improving the wall-plug efficiency of LEDs.

For the purposes of this discussion, an LED can be viewed as having three layers, the active layer sandwiched between a p-doped layer and an n-doped layer. These layers are typically deposited on a substrate such as sapphire. It should be noted that each of these layers typically includes a number of sub-layers. The overall conversion efficiency of an LED depends on the efficiency with which electricity is converted to light in the active layer. Light is generated when holes from the p-doped layer combine with electrons from the n-doped layer in the active layer. Holes that recombine with electrons that do not generate a photon in the desired wavelength decrease the wall-plug efficiency of the LED.

The mobility of the holes is significantly less than that of electrons. Hence, the hole density in the upper most layers of the active layer tends to be higher than in the layers farthest from the p-doped layer. The higher hole density in the upper layers of the active layer results in non-radiative recombination that reduces the wall-plug efficiency. To improve the wall-plug efficiency, schemes in which pits are created in the active layer to expose the sidewalls of the quantum wells so that holes can more uniformly penetrate the various layers of the active layer by entering through the sidewalls of the active layer have been proposed. Typically, the active layer is deposited on an n-type substrate having pits formed therein such that the active layer enters the pits. The active layer is then selectively etched in the pit region to expose the sidewalls of the various quantum well layers so that holes can enter the quantum well layers from the pits to reach the quantum well layers farthest from the p-doped layer without having to pass through the other quantum well layers. This etching operation increases the cost of the resultant devices.

Electrons entering the active layer from the n-doped layer have more mobility and some of these electrons escape into the p-doped layer without having combined with holes in a manner that generates light. To prevent loss of the electrons, an electron barrier layer can be introduced between the p-layer and the active layer. While such a layer reduces the loss of the electrons from the active layer, it also poses a barrier to the holes entering the active layer. To overcome this barrier, the voltage needed to operate the LED must be substantially increased. The additional voltage increases the power that must be utilized to provide a given light output, and hence, reduces the wall-plug efficiency of the LED.

### SUMMARY OF THE INVENTION

The present invention includes a light-emitting device having an n-type semiconductor layer having a plurality of pits with planar regions between the pits, the pits being characterized by sidewalls that intersect the planar regions. A plurality of alternating sub-layers of materials having different bandgaps are deposited on the n-type semiconductor layer. The sub-layers have thicknesses such that the sub-layers form an active layer in the planar regions between the pits and a super lattice on the sidewalls of the pits. A p-type semiconductor layer is deposited on the plurality of alternating sub-layers. One of the sub-layers includes an electron blocking layer. The electron blocking layer is disposed adjacent to the p-type semiconductor layer and extends into the pits. The electron blocking layer is characterized by a first thickness in the substantially planar regions and a second thickness in areas adjacent to the sidewalls of the pits, the second thickness being less than the first thickness.

In one aspect of the invention, the p-type semiconductor layer overlies the substantially planar sub-layers and extends into the pits adjacent to the electron blocking layer.

In another aspect of the invention, the first and second thicknesses are chosen such that 50 percent of the holes from the p-type layer enter the active layer through the sidewalls of the pits.

In a still further aspect of the invention, the active layer includes a plurality of quantum well layers characterized by a first bandgap, and the electron blocking layer includes a material having a second bandgap greater than the first bandgap.

In another aspect of the invention, the active layer includes a plurality of quantum well layers characterized by a first bandgap, and the super lattice is characterized by a second bandgap that is greater than the first bandgap.

### BRIEF DESCRIPTION OF THE DRAWINGS

FIG. 1 is a cross-sectional view of a portion of an ideal LED that has significantly improved hole injection efficiency and an electron blocking layer without substantially increasing the driving voltage of the LED.

FIG. 2 illustrates a portion of a cross-sectional view of an LED according to one embodiment of the present invention during the deposition of the alternating sub-layers which form the active region on the planar region.

FIG. 3 illustrates the portion of LED 40 shown in FIG. 2 after the alternating sub-layers have been deposited and the electron blocking layer and p-layer have been deposited.

FIG. 4 is a cross-sectional view of a portion of the GaN layers through the n-cladding layer of a typical GaN LED formed on a sapphire substrate (or other substrates).

FIG. 5 is an expanded cross-sectional view of a pit in a GaN (or InGaN) layer during the growth of that layer.

### DETAILED DESCRIPTION OF THE PREFERRED EMBODIMENTS OF THE INVENTION

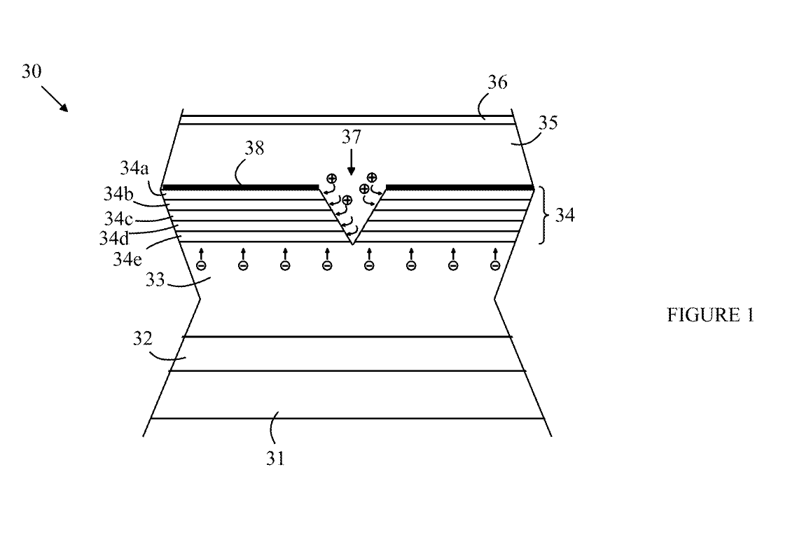

The manner in which the present invention provides its advantages can be more easily understood with reference to FIG. 1, which is a cross-sectional view of a portion of an ideal LED 30 that has significantly improved hole injection efficiency and an electron blocking layer without substantially increasing the driving voltage of the LED. LED 30 is fabricated on a substrate 31 by epitaxially growing a number of layers on substrate 31. The layers include a buffer layer 32, an n-type cladding layer 33, an active layer 34, and a p-type cladding layer 35. A current spreading layer 36 is optionally deposited on the p-cladding layer. Active layer 34 includes a number of sub-layers 34a-34e. To simplify the following discussion, sub-layer 34a will be referred to as the top-most sub-layer; however, this is merely a convenient label and does not imply any particular orientation relative to the earth. Active layer 34 also includes a number of “pits” 37 that extend through the sub-layers of the active layer. To simplify the drawing, only one such pit is shown in the drawing; however, as will be explained in detail below, there is a large number of such pits in active layer 34. P-type cladding layer 35 extends into these pits, and hence, holes from p-type cladding layer 35 can access the sub-layers of active layer 34 through the sidewalls of the pits as well as through the top surface of sub-layer 34a.

An electron blocking layer 38 is deposited between active layer 34 and p-type cladding layer 35 on the horizontal surface of sub-layer 34a. In this arrangement, electrons enter the active layer and travel through the layers in a direction at right angles to the horizontal surface of the active layer. Electrons that do not undergo recombination in the active layer are blocked from leaving through the top surface of the active layer by electron blocking layer 38. Since the electron blocking layer is not present in pit 37, the driving voltage needed to inject the holes into the active layer is not substantially increased.

The arrangement shown in FIG. 1 is an ideal arrangement. As noted above, providing a pit with bare sidewalls is difficult and, typically, requires some form of etching process to expose the walls. The present invention provides the advantages of a structure similar to that shown in FIG. 1 without requiring a complex etching process.

In the following discussion, the “vertical” is defined to be the direction perpendicular to the surface of the growth substrate on which the LED layers are deposited. The “lateral” is defined to be a direction that deviates from the vertical direction more than 45 degrees.

“Selective-area growth” is defined to be a growth pattern in which the crystal growth does not take place uniformly across the majority of the surface owing to some features on the surface. A typical non-uniformity of growth resulted from non-uniformity of the growth chamber such as flows of gases and temperature is not considered in the definition of selective growth, nor is the non-uniformity between wafer center and wafer edge.

In the present invention, a lateral injection path for the holes is created by creating a structure with both lateral p-n junctions and vertical p-n junctions. This structure is engineered such that the turn-on voltage of the vertical p-n junctions is larger than that of the lateral p-n junctions by at least 0.1V. Because the current flow through the p-n junction increases exponentially with voltage, a small turn-on voltage difference can create substantial differences in current flows. Therefore, the hole current flow can be directed to the lateral injection path.

On the other hand, the electron current flow remains mostly vertical because the active areas are selectively deposited on the flat region of the three-dimensional n-region. Without the electron barrier, the electrons would overflow into the p-region under high current injection conditions. With the electron barrier layer, the electrons fall into the active region and, through multiple scattering events with presumably phonons, are confined in the active region because of its smaller bandgap. Thus, the active region becomes a reservoir of electrons. The photon emission becomes possible only if there are vacancies in the valance band. The vacancies are created by the presence of the holes which are injected from the p-layer. Because the turn-on voltage of the lateral p-n junction is made lower than that of the vertical one, the holes are preferentially provided by lateral injection. Hence, a hole can reach any of the quantum well layers without having to pass through another quantum well layer. This arrangement leads to a more uniform hole distribution in the active layer, and hence, higher efficiency in generating photons of the desired wavelength.

The combination of the vertical electron injection and lateral hole injection into the active region creates a unique situation in which the wider bandgap material for the electron barrier does not substantially impede the hole flow laterally. Accordingly, the external quantum efficiency is improved without significantly increasing the turn-on voltage, thus improving the overall wall-plug efficiency.

The present invention utilizes the observation that alternating sub-layers of GaN/InGaN can form two classes of materials depending on the thickness of the wider bandgap material. If the thickness of the wider bandgap material is very thick, the wave functions of electrons and holes cannot penetrate the layer substantially, and the quantization of energy states takes place. In this case, the structure is referred to as a quantum well. If the thickness of the wider bandgap material is not sufficient to contain the wave functions of the electrons and holes, the structure is referred to as a lattice. The electronic properties of a super lattice structure are very similar to those of a uniform alloy of its constituents.

A quantum barrier refers to a layer in which the wider bandgap is sandwiched between narrower bandgap materials. A quantum well refers to a layer with narrow bandgap which is sandwiched between wider bandgap materials. A material can be used for both quantum wells and barriers depending on its surrounding materials.

The present invention makes use of this difference in properties of a structure of alternating sub-layers to generate an active layer on the horizontal planar surfaces of the device while causing the portion of the sub-layers on the walls of the pits to be a super lattice structure. The active layer is defined to be a layer in which holes and electrons recombine and generate light of the desired wavelength. Hence, holes can be injected through the walls of the pits without requiring those holes to penetrate through a quantum well structure even though both structures are deposited in the same sub-layer deposition.

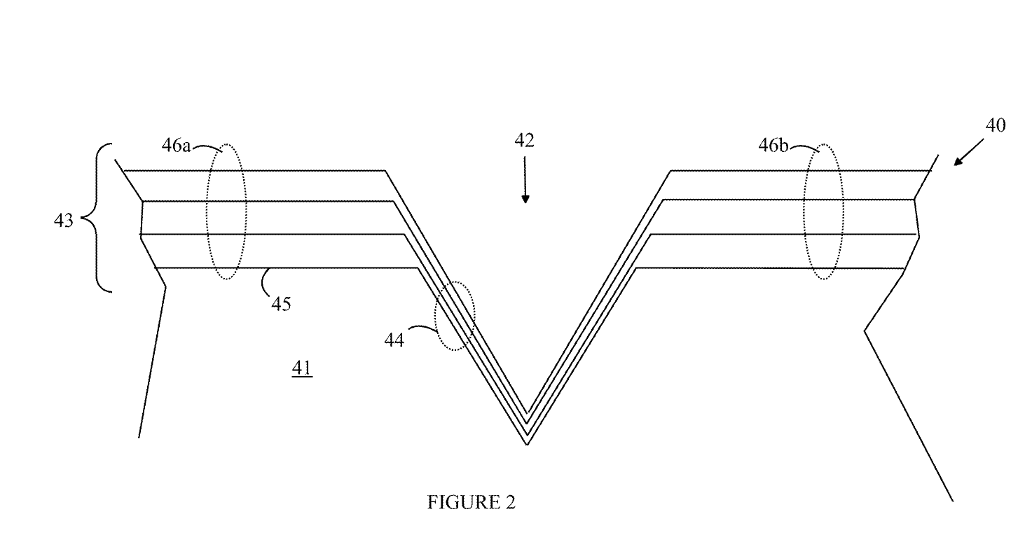

Refer now to FIG. 2, which illustrates a portion of a cross-sectional view of an LED according to one embodiment of the present invention during the deposition of the alternating sub-layers. The portion of LED 40 shown in the figure is the area around a pit 42. The quantum well layers 43 are deposited over an n-type GaN layer 41 having pits formed therein and utilizing growth conditions in which the rate of deposition on the sidewalls 44 of pit 42 is much slower than on the horizontal surface 45 of n-type GaN layer 41. As a result, the thickness of the alternating sub-layers on the lateral surfaces of pit 42 are much less than the thickness of the quantum well layers in regions 46a and 46b.

Methods for generating n-type GaN layer 41 are conventional in the art, and hence, will not be discussed in detail here. For example, U.S. Pat. No. 7,446,345 discloses a method for forming pits in an n-type GaN substrate.

The thickness of the quantum well layers in 46a and 46b are chosen such that an electron will be confined to a quantum well layer. Each quantum well layer typically consists of two layers, a GaN layer and an InGaN layer. The two GaN layers that bound the InGaN layer create quantum barriers that localize electrons trapped therein. If the thickness of the GaN layer is too thin, however, the electron will not be localized in the quantum well (InGaN layer), and the alternating layer structure acts like an uniform alloy of the GaN and InGaN materials, rather than a quantized structure, with an equivalent bandgap somewhere between the bandgaps of those two alternating materials. As noted above, this type of structure is referred to as a super lattice. The distinction of quantum well and super lattice is the penetration depth of the wave function of electrons in the wider bandgap material. When the penetration depth is in the same order of the thickness of the quantum barrier, the electron states are no longer localized and the so-called quantization disappears. Since the thickness of the layers on the walls of the pit is much less than that required to confine an electron, a super lattice is formed on the walls. The super lattice is equivalent to a wider bandgap material compared to the quantum well of the active region.

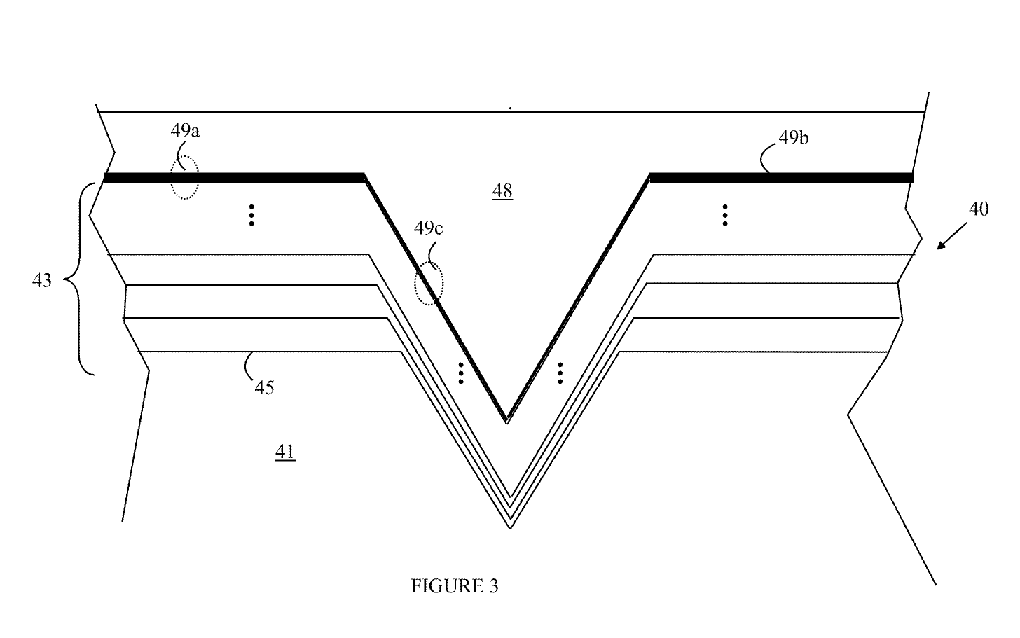

Refer now to FIG. 3, which illustrates the portion of LED 40 shown in FIG. 2 after the quantum well layers have been deposited and the electron blocking layer and p-layer have been deposited. Note that the thickness of the electron blocking layer needs to be thicker than the penetration depth of the electron wave function. Typically, a barrier of 0.3 eV with the thickness of 5 nm is sufficient to block the electrons. On the other hand, because of the much larger effective mass of holes, the penetration depth of holes into a quantum barrier is very small. Often a quantum barrier of 0.1 eV for 2 nm is effective to block hole transport across the barrier. In order to facilitate hole transport across the quantum barrier, additional voltage is applied to raise the potential energy of the hole in the p-GaN layer.

The electron blocking layer is deposited using a growth regime in which the thickness of the electron blocking layer on the horizontal surfaces of the active layer is greater than the thickness on the walls of the pit. That is, the thickness of the electron blocking layer in regions 49a and 49b is greater than the thickness of the electron blocking layer in region 49c. As a result, the voltage needed to overcome the electron blocking layer in region 49c is less than that in regions 49a and 49b. Since the hole current is an exponential function of the voltage difference between the p-region 48 and n-type GaN layer 41, even a small difference in the electron blocking layer barrier can lead to a large difference in the hole current. In one aspect of the invention, the reduced thickness of the electron blocking layer in region 49c is sufficient to lower the turn-on voltage of the p-n junction in region 49c by at least 0.1V.

Accordingly, holes are preferentially injected into the quantum well layers through the sidewalls of the quantum well layers accessed through the pit. In one aspect of the invention, at least 50 percent of the holes are injected into the quantum well layers through the sidewalls of the pits.

In one aspect of the invention the super lattice on the sides of the pits has a bandgap that is wider than that of quantum well layers. This reduces the absorption of the light emission from the quantum well layers by the super lattice. In addition, the wider bandgap prevents the super lattice from confining electrons or holes.

The electron blocking layer utilizes a material that has a wider bandgap than that of the p-GaN material. In a GaN material system, AlGaInN can be utilized for the electron blocking layer. The electron blocking layer prevents thermionic emission of electrons from the n-GaN and active layer into the pGaN region. The ability of a hole to tunnel through the electron blocking layer is poor due the larger effective mass of a hole. In the present invention, this problem is overcome by utilizing a very thin electron blocking layer on the sides of the pit.

Owing to its heavy effective mass, the ability for the hole to tunnel through the barrier is poor unless the electron blocking layer is very thin. Hence, if the electron blocking layer is thick on top of the planar surface of the LED and very thin on the sides of pits, the hole injection efficiencies in the pits will be much greater than the hole injection efficiency on the planar surface. Because the injection efficiency typically varies exponentially with voltage, a very small difference in voltage can create a very large difference in hole injection efficiency. Hence, in spite of the much smaller area on the sides of the pits relative to the planar area on the horizontal surface of the LED layers, most of the hole current can be directed into the quantum well layers by the sides of the pit under the same electrical bias condition.

In one aspect of the present invention, the pits in the active layer are formed with the aid of the dislocations that arise from the difference in lattice constant between the materials from which the LED is constructed and the underlying substrate. For example, GaN-based LEDs that are fabricated on sapphire, SiC, or Si substrates include vertically propagating dislocations that result from the difference in lattice constant between the GaN-based materials and the substrate material. In principle, any substrate that provides vertically-propagating dislocations in sufficient numbers can be utilized.

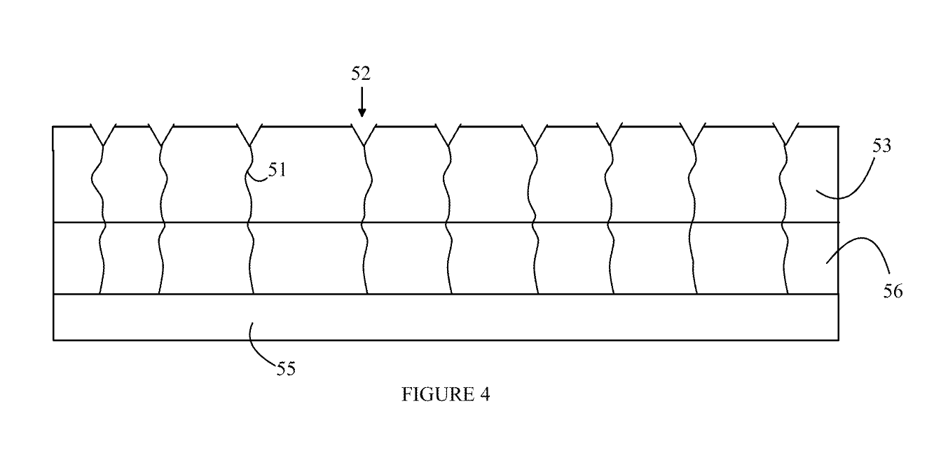

Refer now to FIG. 4, which is a cross-sectional view of a portion of the GaN layers through the n-cladding layer of a typical GaN LED formed on a sapphire substrate. The GaN layers are deposited on a sapphire substrate 55 whose lattice constant differs from the GaN layers. The difference in lattice constant gives rise to dislocations that propagate through the various layers as the layers are deposited. An exemplary dislocation is labeled at 51. The density of such dislocation is typically 10⁷ to 10¹¹ per cm² in a GaN LED deposited on a sapphire substrate. The number of dislocations that propagate into the n-cladding layer 53 depends on the nature of a buffer layer 56 and the growth conditions under which buffer layer 56 and n-cladding layer 53 are deposited. The dislocations give rise to small pits on the surface of the uppermost layer of material such as pit 52. The size of these pits depends on the growth conditions under which the GaN material is deposited during the epitaxial growth of the layers.

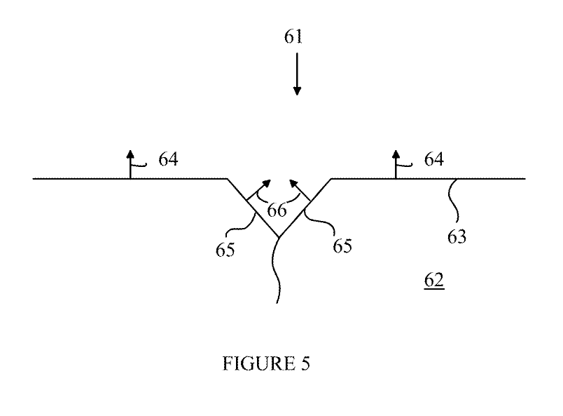

Refer now to FIG. 5, which is an expanded cross-sectional view of a pit 61 in a GaN (or InGaN) layer 62 during the growth of that layer. During the growth phase, material is added to the crystal facets of GaN layer 62 as shown by arrows 64 and 66. The crystal facet shown at 63 is typically the c-facet of the GaN crystal. At the dislocations, additional facets such as facets 65 are exposed in addition to facet 63. The rate of growth on the different facets can be adjusted by the growth conditions such that the rate of growth of the facets 65 exposed in the pit is greater than or less than that of the rate of growth of the facet 63. If the rate of growth of facets 65 is less than that of facet 63, the size of the pit will increase as material is deposited.

Referring again to FIG. 3, after the electron blocking layer is deposited, the surface of the device is planarized by filling in the pits with p-GaN. The filling employs the opposite growth mode to that used in depositing the active layer and the electron blocking layer. That is, the deposition is performed at an increased temperature and growth rate relative to the temperatures and growth rates used to deposit the active layer and the electron blocking layer. In this mode, the atoms are deposited on the sides of the pits much faster than on the planar area. As a result, a planar p-GaN layer having projections that fill the pits is formed as shown at 48.

In one exemplary embodiment, the thickness of the active region (in the planar region) is about 100 nm. The dimension of the ph is in the same order. In order to fill the ph, a thickness of 300 nm p-GaN is sufficient to achieve a planar surface.

The above-described embodiments utilize the GaN family of materials. For the purposes of this discussion, the GaN family of materials is defined to be all alloy compositions of GaN, MN and MN. However, embodiments that utilize other material systems and substrates can also be constructed according to the teachings of the present invention.

The substrate on which the n-type GaN layer is formed can be any of a number of substrates including silicon, sapphire, and SiC provided the appropriate buffer layers are grown to mitigate the effects of the different lattice constants between the substrates and the GaN layers. It will be appreciated that the density of dislocations can be adjusted by the choice of substrate and buffer layers.

The above-described embodiments are described in terms of “top” and “bottom” surfaces of the various layers. In general, the layers are grown from the bottom surface to the top surface to simplify the discussion. However, it is to be understood that these are merely convenient labels and are not to be taken as requiring any particular orientation with respect to the Earth.

The above-described embodiments of the present invention have been provided to illustrate various aspects of the invention. However, it is to be understood that different aspects of the present invention that are shown in different specific embodiments can be combined to provide other embodiments of the present invention. In addition, various modifications to the present invention will become apparent from the foregoing description and accompanying drawings. Accordingly, the present invention is to be limited solely by the scope of the following claims.

What is claimed is:

1. A light-emitting device comprising:
an n-type semiconductor layer having a plurality of pits with substantially planar regions between said pits, said pits being characterized by sidewalls that intersect said planar regions;
a plurality of alternating sub-layers of materials having different bandgaps deposited on said n-type semiconductor layer, said sub-layers having thicknesses such that said plurality of alternating sub-layers form an active layer in said planar regions between said pits and a super lattice on said sidewalls of said pits, said active layer generating light when holes and electrons combine therein; and
a p-type semiconductor layer deposited on said plurality of alternating sub-layers, wherein
one of said plurality of alternating sub-layers comprises an electron blocking layer, said electron blocking layer being disposed adjacent to said p-type semiconductor layer and extending into said pits, said electron blocking layer being characterized by a first thickness in said substantially planar regions and a second thickness in areas adjacent to said sidewalls of said pits, said second thickness being less than said first thickness.

2. The light-emitting device of claim 1 wherein said p-type semiconductor layer overlies said substantially planar sub-layers and extends into said pits adjacent to said electron blocking layer.

3. The light-emitting device of claim 1 wherein said first and second thicknesses are chosen such that 50 percent of said holes from said p-type layer enter said active layer through said sidewalls of said pits.

4. The light-emitting device of claim 1 wherein said active layer comprises a plurality of quantum well layers characterized by a first bandgap and wherein said electron blocking layer comprises a material having a second bandgap greater than said first bandgap.

5. The light-emitting device of claim 1 wherein said active layer comprises a plurality of quantum well layers characterized by a first bandgap and wherein said super lattice is characterized by a second bandgap that is greater than said first bandgap.

6. The light-emitting device of claim 1 wherein said n-type semiconductor layer, said p-type semiconductor layer and said active layer comprise materials from the GaN family of materials.

7. The light-emitting device of claim 1 wherein said electron blocking layer comprises AlGaInN.

8. A method for fabricating a light-emitting device, said method comprising:
depositing an n-type semiconductor layer having a plurality of pits with substantially planar regions between said pits, said pits being characterized by sidewalls that intersect said planar regions;
depositing a plurality of alternating sub-layers of materials having different bandgaps on said n-type semiconductor layer, said sub-layers having thicknesses such that said sub-layers form an active layer in said planar regions between said pits and a super lattice on said sidewalls of said pits; and
depositing a p-type semiconductor layer on said plurality of alternating sub-layers, wherein
one of said plurality of alternating sub-layers comprises an electron blocking layer, said electron blocking layer being disposed adjacent to said p-type semiconductor layer and extending into said pits, said electron blocking layer being characterized by a first thickness in said substantially planar regions and a second thickness in areas adjacent to said sidewalls of said pits, said second thickness being less than said first thickness.

9. The method of claim 8 wherein said p-type semiconductor layer overlies said substantially planar sub-layers and extends into said pits adjacent to said electron blocking layer.

10. The method of claim 8 wherein said first and second thicknesses are chosen such that 50 percent of said holes from said p-type layer enter said active layer through said sidewalls of said pits.

11. The method of claim 8 wherein said active layer comprises a plurality of quantum well layers characterized by a first bandgap and wherein said electron blocking layer comprises a material having a second bandgap greater than said first bandgap.

12. The method of claim 8 wherein said active layer comprises a plurality of quantum well layers characterized by a first bandgap and wherein said super lattice is characterized by a second bandgap that is greater than said first bandgap.

13. The method of claim 8 wherein said n-type semiconductor layer, said p-type semiconductor layer and said active layer comprise materials from the GaN family of materials.

14. The method of claim 8 wherein said electron blocking layer comprises AlGaInN.
